(19) United States
(12) Patent Application Publication
(10) Pub. No.: US 2022/0308460 A1
(43) Pub. Date: Sep. 29, 2022

(54) METHOD TO FABRICATE LARGE SCALE FLAT OPTICS LENSES

(71) Applicant: Applied Materials, Inc., Santa Clara, CA (US)

(72) Inventors: Yongan XU, Santa Clara, CA (US); Naamah ARGAMAN, San Jose, CA (US); David SELL, Santa Clara, CA (US); Ludovic GODET, Sunnyvale, CA (US)

(21) Appl. No.: 17/701,394

(22) Filed: Mar. 22, 2022

Related U.S. Application Data
(60) Provisional application No. 63/165,572, filed on Mar. 24, 2021.

(51) Int. Cl. G03F 7/20; G03F 7/00

(52) U.S. Cl. CPC G03F 7/70366; G03F 7/0005

(57) ABSTRACT

Methods of fabricating large-scale optical devices having sub-micron dimensions are provided. A method is provided that includes projecting a beam to a mask, the mask corresponding to a section of an optical device pattern, the optical device pattern divided into four or more equal portions, each portion corresponding to a section of a substrate. The method further includes scanning the mask over a first section of the substrate to pattern a first portion of the optical device pattern, the substrate is positioned at a first rotation angle relative to the mask. The method further includes rotating the substrate to a second rotation angle, the second rotation angle corresponding to 360° divided by a total number of portions of the optical device pattern, scanning the mask over a second section of the substrate from the initial position to the final position to pattern a second portion of the optical device pattern.

### CROSS-REFERENCE TO RELATED APPLICATIONS

This application claims benefit of U.S. Provisional Patent Application No. 63/165,572, filed Mar. 24, 2021, which is herein incorporated by reference in its entirety.

### BACKGROUND

### Field

Embodiments of the present disclosure generally relate to optical device fabrication. In particular, embodiments described herein relate to methods of fabricating large-scale optical devices having sub-micron dimensions.

### Description of the Related Art

Optical devices may be used to manipulate the propagation of light using structures of the optical device formed on a substrate. These structures alter light propagation by inducing localized phase discontinuities (i.e., abrupt changes of phase over a distance smaller than the wavelength of light). These structures may be composed of different types of materials, shapes, or configurations on the substrate and may operate based upon different physical principles.

Optical devices may be fabricated from a substrate having a diameter of 200 mm or greater, such as a 200 mm or 300 mm substrate. The substrate may be processed to form multiple optical devices. However, it may be beneficial to fabricate a single large-scale optical device, i.e., an optical device having a diameter of 200 mm or greater that includes optical device structures having sub-micron critical dimensions. Conventionally, lithography of a substrate to form an optical device pattern of a large-scale optical device requires either a substrate-sized mask or multiple masks stitched together. The substrate-sized mask may result in reduced resolution, and multiple masks stitched together may result in patterning errors.

Accordingly, what is needed in the art are methods of fabricating large-scale optical devices having sub-micron dimensions.

### SUMMARY

Methods of fabricating large-scale optical devices having sub-micron dimensions are provided. In one embodiment, a method is provided that includes projecting a beam to a mask, the mask corresponding to a section of an optical device pattern, the optical device pattern divided into four or more equal portions, each portion corresponding to a section of a substrate. The method further includes scanning the mask over a first section of the substrate to pattern a first portion of the optical device pattern, the substrate is positioned at a first rotation angle relative to the mask, wherein the scanning of the mask over the first section comprises moving one of the mask or the substrate from an initial position to a final position. The method further includes rotating the substrate to a second rotation angle, the second rotation angle corresponding to 360° divided by a total number of portions of the optical device pattern, scanning the mask over a second section of the substrate from the initial position to the final position to pattern a second portion of the optical device pattern, wherein the scanning of the mask over the second section comprises moving one of the mask or the substrate from the initial position to the final position, and repeating the rotating the substrate at subsequent rotation angles and the scanning of the mask over subsequent sections of the substrate until the substrate is patterned with the each of the four or more equal portions of the optical device pattern.

In another embodiment, a method is provided that includes projecting a beam to a mask, the mask corresponding to a section of an optical device pattern, the optical device pattern divided into four or more equal portions, each portion corresponding to a section of a substrate. The method further includes scanning the mask over a first section of the substrate to pattern a first portion of the optical device pattern, the substrate is positioned at a first rotation angle relative to the mask, wherein the scanning of the mask over the first section comprises moving one of the mask or the substrate from an initial position to a final position. The method further includes rotating the substrate to a second rotation angle, the second rotation angle corresponding to 360° divided by a total number of portions of the optical device pattern, scanning the mask over a second section of the substrate from the initial position to the final position to pattern a second portion of the optical device pattern, wherein the scanning of the mask over the second section comprises moving one of the mask or the substrate from the initial position to the final position, repeating the rotating the substrate at subsequent rotation angles and the scanning of the mask over subsequent sections of the substrate until the substrate is patterned with the each of the four or more equal portions of the optical device pattern, and etching the substrate.

In another embodiment, a method is provided that includes projecting a beam to a mask, the mask corresponding to a section of an optical device pattern, the optical device pattern divided into four or more equal portions, each portion corresponding to a section of a substrate. The method further includes scanning the mask over a first section of the substrate to pattern a first portion of the optical device pattern, the substrate is positioned at a first rotation angle relative to the mask, wherein the scanning of the mask over the first section comprises moving one of the mask or the substrate from an initial position to a final position, and etching the first section of the substrate. The method further includes rotating the substrate to a second rotation angle, the second rotation angle corresponding to 360° divided by a total number of portions of the optical device pattern, scanning the mask over a second section of the substrate from the initial position to the final position to pattern a second portion of the optical device pattern, wherein the scanning of the mask over the second section comprises moving one of the mask or the substrate from the initial position to the final position, and etching the second section of the substrate. The method further includes repeating the rotating the substrate at subsequent rotation angles, the scanning of the mask over subsequent sections of the substrate, and the etching of subsequent sections until the substrate is patterned with the each of the four or more equal portions of the optical device pattern.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of scope, as the disclosure may admit to other equally effective embodiments.

FIG. 1A is a schematic, plan view of an optical device according to one or more embodiments.

FIG. 1B is a schematic, cross-sectional view of a portion of the optical device of FIG. 1A according to one or more embodiments.

FIG. 2 is a schematic, perspective view of a lithography tool according to one or more embodiments

FIG. 3 is a flow diagram of a method of fabricating an optical device according to one or more embodiments.

FIGS. 4A and 4B are schematic, plan views of an optical device substrate according to one or more embodiments.

FIGS. 5A and 5B are schematic, plan views of an optical device substrate according to one or more embodiments.

FIGS. 6A and 6B are schematic, plan views of an optical device substrate according to one or more embodiments.

FIGS. 7A and 7B are schematic, plan views of an optical device substrate according to one or more embodiments.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present subject matter generally relate to optical device fabrication. In particular, embodiments described herein relate to methods of fabricating large-scale optical devices having sub-micron dimensions.

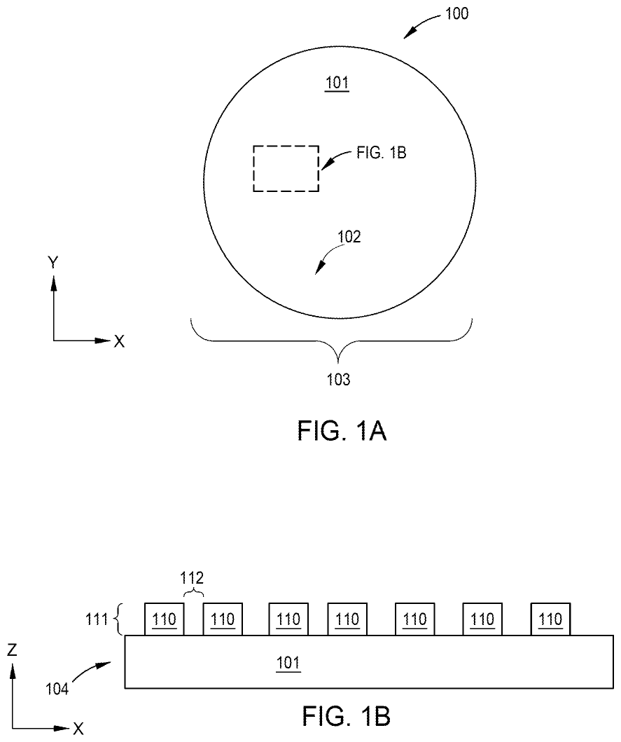

FIG. 1A is a schematic, plan view of an optical device 100 according to one or more embodiments. The optical device 100 is fabricated from the method 300 described herein. The optical device 100 includes an optical device substrate 101 having a plurality of optical device structures 110 disposed on a surface 102. The optical device substrate 101 has a diameter 103 that is 200 mm or greater, e.g., 300 mm or greater. The optical device substrate 101 may be any suitable substrate on which an optical device may be formed. In one embodiment, which can be combined with other embodiments described herein, the optical device substrate 101 is a silicon-containing substrate. It is also contemplated that the optical device substrate 101 may be an indium, gallium, germanium, or nitrogen containing substrate. Alternatively or additionally, the optical device substrate 101 may be a layered substrate.

FIG. 1B is a schematic, cross-sectional view of a portion 104 of the optical device 100 of FIG. 1A according to one or more embodiments. A plurality of optical device structures 110 having a depth 111 are disposed on the surface 102 of the optical device substrate 101. The optical device structures 110 may be nanostructures having sub-micron dimensions, e.g., nano-sized dimensions. The optical device structures 110 have critical dimensions 112, e.g., one of the width or diameter of the optical device structures 110, the pitch of the optical device structures 110, or the gap between the optical device structures 110. In one embodiment, which may be combined with other embodiments described herein, the critical dimension 112 is less than 1 micrometer (μm) and corresponds to the width or diameter of the optical device structures 110, depending on the cross-section of the optical device structures 110. While FIG. 1B depicts the optical device structures 110 as having square or rectangular shaped cross-sections, the cross-sections of the optical device structures 110 may have other shapes including, but not limited to, circular, triangular, elliptical, regular polygonal, irregular polygonal, and/or irregular shaped cross-sections. In some embodiments, which can be combined with other embodiments described herein, the cross-sections of the optical device structures 110 on a single optical device substrate 101 are different.

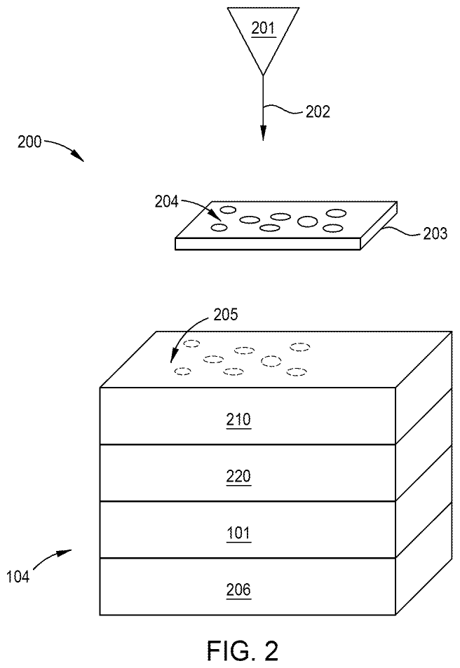

FIG. 2 is a schematic, perspective view of a lithography tool 200 according to one or more embodiments. The lithography tool 200 is utilized for photolithography or electron beam (e-beam) lithography. Photolithography includes, but is not limited to, I-line lithography at 365 nanometers (nm), krypton fluoride (KrF) lithography at 248 nm, argon fluoride (ArF) dry lithography at 193 nm, argon fluoride (ArF) immersion lithography at 193 nm, and extreme ultraviolet (EUV) lithography at 13.5 nm. The optical device substrate 101 shown in FIG. 2 corresponds to the portion 104 of the optical device substrate 101. The lithography tool 200 includes a source 201 and a stage 206. The optical device substrate 101 is disposed on the stage 206. The stage 206 includes an actuator operable to rotate the optical device substrate 101 in order to scan the optical device substrate 101 in X and Y directions.

In embodiments of photolithography, a mask 203 is a physical mask and includes one or more apertures 204 corresponding to an optical device pattern 205. A beam 202 is projected by the source 201 through the one or more apertures 204 to form the optical device pattern 205 in a resist layer 210 disposed on the optical device substrate 101. The mask 203 is coupled to an actuator (not shown) to scan in X and Y directions in order to pattern the entirety of the optical device substrate 101. The mask 203 is rectangular-shaped and is about 26 mm by 33 mm or less, although other sizes are also contemplated. In embodiments utilizing photolithography, the source 201 is a light source, and the beam 202 is a light beam.

In embodiments using e-beam lithography, the source 201 projects the beam 202 with the optical device pattern 205 such that the source 201 operates as a virtual mask. Accordingly, the mask 203 is a virtual mask corresponding to the optical device pattern 205 formed in the resist layer 210 disposed on the optical device substrate 101. In embodiments of e-beam lithography, the source 201 is an e-beam source, and the beam 202 is an e-beam.

The resist layer 210 is a positive resist or a negative resist. A positive resist includes portions of the resist layer 210, which, when exposed to a beam, are respectively soluble to a resist developer applied to the resist layer 210 after the optical device pattern 205 is written into the resist layer 210 using the beam. A negative resist includes portions of the resist layer 210, which, when exposed to a beam, will be respectively insoluble to the resist developer applied to the resist layer 210 after the optical device pattern 205 is written into the resist layer 210 using the beam. The chemical composition of the resist layer 210 determines whether the resist layer 210 is a positive resist or a negative resist.

In one embodiment, which can be combined with other embodiments described herein, a hardmask 220 is disposed between the resist layer 210 and the optical device substrate 101. The hardmask 220 may be utilized for direct etching of the optical device substrate 101 to form the optical device structures 110 of the optical device 100.

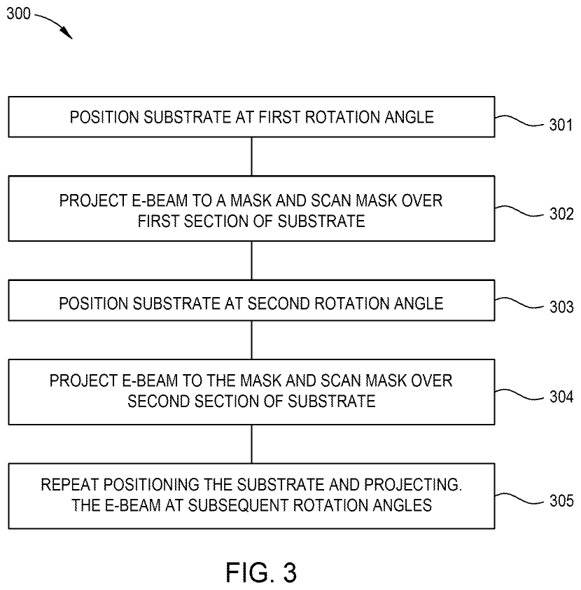

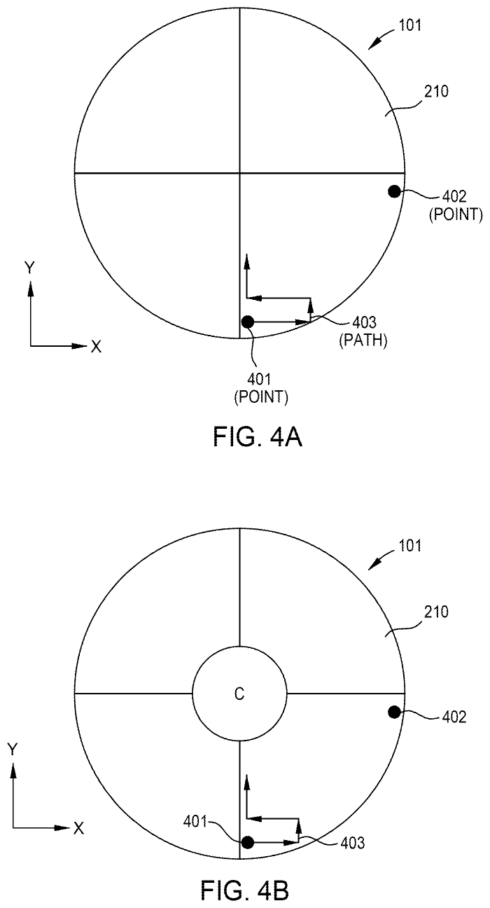

FIG. 3 is a flow diagram of a method 300 of fabricating an optical device 100 according to one or more embodiments. To facilitate explanation, the method 300 will be described with reference to the lithography tool 200 of FIG. 2. However, it is contemplated that other suitably configured patterning tools other than the lithography tool 200 may be utilized in conjunction with method 300. In addition, method 300 will also be described with reference to FIGS. 4A, 4B, 5A, 5B, 6A, 6B, 7A, and 7B, which are schematic, plan views of an optical device substrate 101 according to one or more embodiments.

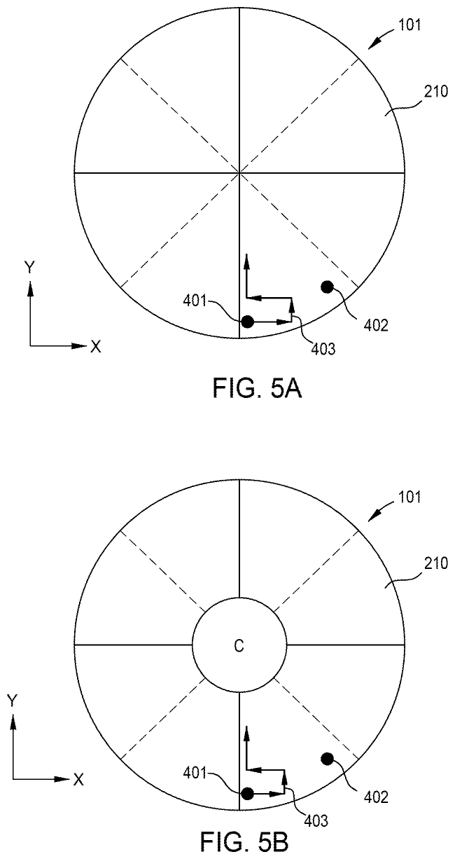

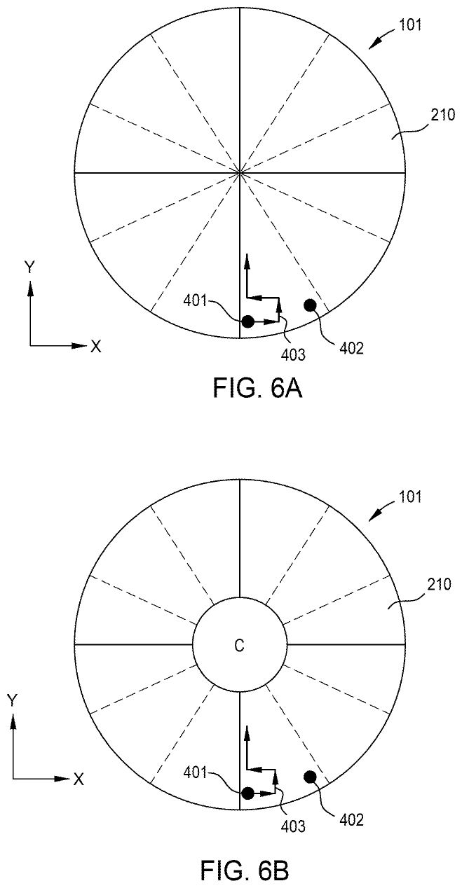

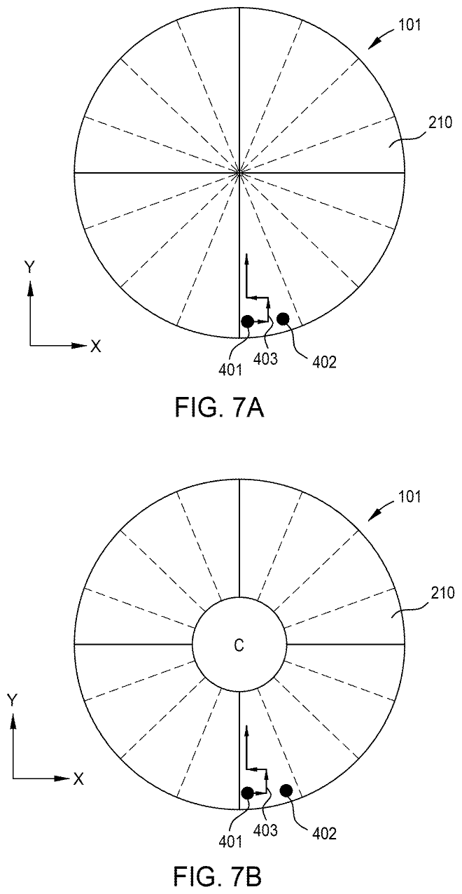

The resist layer 210 is disposed on the optical device substrate 101 such that the optical device pattern 205 is formed on the resist layer 210. The optical device substrate 101 of FIG. 4A has four equal sections corresponding to the optical device pattern 205 divided into four equal portions. The optical device substrate 101 of FIG. 5A has eight equal sections corresponding to the optical device pattern 205, which is divided into eight equal portions. The optical device substrate 101 of FIG. 6A has twelve equal sections corresponding to the optical device pattern 205, which is divided into twelve equal portions. The optical device substrate 101 of FIG. 7A has sixteen equal sections corresponding to the optical device pattern 205, which is divided into sixteen equal portions.

As depicted in FIG. 4B, the optical device substrate 101 may include a central section C of the optical device substrate 101 in addition to the four equal portions. The central section C eliminates an intersection point at the center of the device area of the optical device substrate 101. As depicted in FIG. 5B, the optical device pattern 205 is divided into eight equal portions and a central portion corresponding to eight equal sections and a central section C of the optical device substrate 101. As depicted in FIG. 6B, the optical device pattern 205 is divided into twelve equal portions and a central portion corresponding to twelve equal sections and central section C of the optical device substrate 101. As depicted in FIG. 7B, the optical device pattern 205 is divided into sixteen equal portions and a central portion corresponding to sixteen equal sections and a central section C of the optical device substrate 101.

At operation 301, the optical device substrate 101 is positioned at a first rotation angle relative to the mask. The optical device pattern 205 is divided into four or more equal portions, each portion corresponding to a section of the optical device substrate 101, as shown in FIGS. 4A-7B. The beam 202 is projected to the mask 203, which corresponds to a portion of the optical device pattern 205. By dividing the optical device pattern 205 into portions, high resolution (i.e., sub-micron dimensions) and reduced patterning errors can be achieved for the resulting optical device structures 110 formed on the optical device substrate 101.

At operation 302, the beam 202 is projected to the mask 203, and the mask 203 is scanned over a first section of the optical device substrate 101 while the optical device substrate 101 is positioned at the first rotation angle relative to the mask 203. This scan patterns a first portion of the optical device pattern 205 on the first section of the optical device substrate 101. Scanning of the mask 203 over the first section involves moving one of the mask 203 or the optical device substrate 101 along a path 403. The path 403 covers the designated portion of the optical device substrate 101 from an initial position 401 to a final position 402.

At operation 303, the optical device substrate 101 is positioned at second rotation angle. In one embodiment, which can be combined with other embodiments described herein, the optical device substrate 101 is rotated to the second rotation angle by activating the actuator coupled to the stage 206. The second rotation angle corresponds to 360° divided by a total number of portions of the optical device pattern 205. For example, if the optical device pattern 205 is divided into four portions, the second rotation angle is 90°. At the second rotation angle, the second section of the optical device pattern 205 aligns with the mask 203, the initial position 401, and final position 402.

The proper alignment of the optical device substrate 101 during each rotation allows for uniform formation of the optical device pattern 205. In one embodiment, which can be combined with other embodiments described herein, a plurality of alignment marks (not shown) are printed on the optical device substrate 101. Any suitable number of alignment marks may be used; for example, in one embodiment, four or more alignment marks are disposed on the optical device substrate 101. In one embodiment, which can be combined with other embodiments described herein, the alignment marks are formed on an outer edge of the optical device substrate 101 in order to minimize impact on the device area. When rotating the optical device substrate 101, the position of the optical device substrate 101 relative to a pre-determined position is monitored using the alignment marks.

At operation 304, the beam 202 is projected to the mask 203, and the mask 203 is scanned over a second section of the optical device substrate 101 while the optical device substrate 101 is positioned at the second rotation angle relative to the mask 203. This scan patterns a second portion of the optical device pattern 205 on the second section of the optical device substrate 101. As with the scanning over the first section, scanning of the mask 203 over the second section involves moving one of the mask 203 or the optical device substrate 101 along the path 403. The path 403 covers the designated portion of the optical device substrate 101 from the initial position 401 to the final position 402.

At operation 305, rotating the optical device substrate 101 at subsequent rotation angles and scanning the mask 203 over subsequent sections repeats until the optical device substrate 101 is patterned with the each of the four or more equal portions of the optical device pattern 205. Scanning of the mask 203 over subsequent sections involves moving one of the mask 203 or the optical device substrate 101 along the path 403. In one embodiment, which can be combined with other embodiments described herein, the optical device substrate 101 undergoes an etching process after the patterning process is complete for each of the four or more equal portions of the optical device pattern 205. In another embodiment, which can be combined with other embodiments described herein, the optical device substrate 101 undergoes an etching process after each of the sections are patterned. For example, if there are four sections, the first section undergoes the etching process before the second section is scanned and patterned.

In summation, embodiments described herein relate to methods of fabricating large-scale optical devices having sub-micron dimensions. By patterning the substrate in portions, high resolution (i.e., sub-micron dimensions) can be achieved for the resulting optical device structures formed on the substrate. The fabricated optical devices, or lenses, may be used in applications requiring relatively large lenses, such as satellite imaging or communication. The methods described herein reduce errors that may arise during patterning of large optical device substrates.

While the foregoing is directed to embodiments of the present disclosure, other and further embodiments of the disclosure may be devised without departing from the basic scope thereof, and the scope thereof is determined by the claims that follow.

What is claimed is:

1. A method, comprising:
projecting a beam to a mask, the mask corresponding to a section of an optical device pattern, the optical device pattern divided into four or more equal portions, each portion corresponding to a section of a substrate;
scanning the mask over a first section of the substrate to pattern a first portion of the optical device pattern, the substrate is positioned at a first rotation angle relative to the mask; wherein:
the scanning of the mask over the first section comprises moving one of the mask or the substrate from an initial position to a final position;
rotating the substrate to a second rotation angle, the second rotation angle corresponding to 360° divided by a total number of portions of the optical device pattern;
scanning the mask over a second section of the substrate from the initial position to the final position to pattern a second portion of the optical device pattern, wherein:
the scanning of the mask over the second section comprises moving one of the mask or the substrate from the initial position to the final position; and
repeating the rotating the substrate at subsequent rotation angles and the scanning of the mask over subsequent sections of the substrate until the substrate is patterned with the each of the four or more equal portions of the optical device pattern.

2. The method of claim 1, further comprising:
etching the substrate.

3. The method of claim 1, further comprising:
printing four or more alignment marks on the substrate.

4. The method of claim 3, wherein rotating the substrate comprises rotating the substrate to a pre-determined position using the alignment marks.

5. The method of claim 1, wherein a hardmask is disposed on the substrate, and a resist layer is disposed on the hardmask.

6. The method of claim 1, wherein the beam is an electron beam or a light beam.

7. The method of claim 1, wherein a diameter of the substrate is 200 mm or greater.

8. The method of claim 1, wherein patterning the substrate comprises forming optical device structures, wherein a critical dimension of the optical device structures is less than 1 micron.

9. The method of claim 1, wherein the mask is a physical mask.

10. The method of claim 9, wherein the mask is rectangular-shaped, and the mask is about 26 mm by 33 mm or less.

11. The method of claim 1, wherein the mask is a virtual mask corresponding to the optical device pattern.

12. A method, comprising:
projecting a beam to a mask, the mask corresponding to a section of an optical device pattern, the optical device pattern divided into four or more equal portions, each portion corresponding to a section of a substrate;
scanning the mask over a first section of the substrate to pattern a first portion of the optical device pattern, the substrate is positioned at a first rotation angle relative to the mask; wherein:
the scanning of the mask over the first section comprises moving one of the mask or the substrate from an initial position to a final position;
rotating the substrate to a second rotation angle, the second rotation angle corresponding to 360° divided by a total number of portions of the optical device pattern;
scanning the mask over a second section of the substrate from the initial position to the final position to pattern a second portion of the optical device pattern, wherein:
the scanning of the mask over the second section comprises moving one of the mask or the substrate from the initial position to the final position;
repeating the rotating the substrate at subsequent rotation angles and the scanning of the mask over subsequent sections of the substrate until the substrate is patterned with the each of the four or more equal portions of the optical device pattern; and
etching the substrate.

13. The method of claim 12, further comprising:
printing four or more alignment marks on the substrate.

14. The method of claim 13, wherein rotating the substrate comprises rotating the substrate to a pre-determined position using the alignment marks.

15. The method of claim 12, wherein a diameter of the substrate is 200 mm or greater.

16. The method of claim 12, wherein patterning the substrate comprises forming optical device structures, wherein a critical dimension of the optical device structures is less than 1 micron.

17. A method, comprising:
projecting a beam to a mask, the mask corresponding to a section of an optical device pattern, the optical device pattern divided into four or more equal portions, each portion corresponding to a section of a substrate;
scanning the mask over a first section of the substrate to pattern a first portion of the optical device pattern, the substrate is positioned at a first rotation angle relative to the mask; wherein:
the scanning of the mask over the first section comprises moving one of the mask or the substrate from an initial position to a final position;
etching the first section of the substrate;
rotating the substrate to a second rotation angle, the second rotation angle corresponding to 360° divided by a total number of portions of the optical device pattern;
scanning the mask over a second section of the substrate from the initial position to the final position to pattern a second portion of the optical device pattern, wherein:
the scanning of the mask over the second section comprises moving one of the mask or the substrate from the initial position to the final position;
etching the second section of the substrate; and
repeating the rotating the substrate at subsequent rotation angles, the scanning of the mask over subsequent sections, and etching of subsequent sections until the substrate is patterned with the each of the four or more equal portions of the optical device pattern.

18. The method of claim 17, further comprising:
printing four or more alignment marks on the substrate.

19. The method of claim 18, wherein rotating the substrate comprises rotating the substrate to a pre-determined position using the alignment marks.

20. The method of claim 17, wherein a diameter of the substrate is 200 mm or greater.
